(19) United States
(12) Patent Application Publication
(10) Pub. No.: US 2016/0293635 A1
(43) Pub. Date: Oct. 6, 2016

(54) DISPLAY DEVICE AND MANUFACTURING METHOD THEREOF

(71) Applicant: Samsung Display Co., Ltd., Yongin-si (KR)

(72) Inventors: Chang Oh JEONG, Yongin-si (KR); Hyun Eok SHIN, Yongin-si (KR); Su Kyoung YANG, Yongin-si (KR); Chan Woo YANG, Yongin-si (KR); Dong Min LEE, Yongin-si (KR)

(21) Appl. No.: 14/984,638

(22) Filed: Dec. 30, 2015

(30) Foreign Application Priority Data
Apr. 6, 2015 (KR) 10-2015-0048610

(51) Int. Cl. H01L 27/12; H01L 51/52; G02F 1/1343; H01L 29/423; G02F 1/1368; H01L 27/32; H01L 51/00

(52) U.S. Cl. CPC H01L 27/124; H01L 27/3276; H01L 51/5271; H01L 27/1259; H01L 27/3248; H01L 27/3265; H01L 27/3262; H01L 51/0023; H01L 51/5221; H01L 29/42384; G02F 1/1368; G02F 1/13439; G02F 1/134309; H01L 2251/308; H01L 2251/306; H01L 2227/323

(57) ABSTRACT

A display device includes a gate line, a data line crossing the gate line, and a first transistor including a gate electrode electrically coupled to the gate line and a first electrode electrically coupled to the data line. At least one of the gate electrode of the first transistor, the first electrode of the first transistor, and a second electrode of the first transistor includes at least one of a first conductor layer and a second conductor layer. The first conductor layer includes a first metal layer and a second metal layer disposed on the first metal layer. The second conductor layer includes a third metal layer and a fourth metal layer disposed on the third metal layer. The second metal layer has a lower reflectivity than the first metal layer. The fourth metal layer has a lower reflectivity lower than the third metal layer.

### CROSS-REFERENCE TO RELATED APPLICATION

This application claims priority from and the benefit of Korean Patent Application No. 10-2015-0048610, filed on Apr. 6, 2015, which is hereby incorporated by reference for all purposes as if fully set forth herein.

### BACKGROUND

1. Field

Exemplary embodiments relate to a display device including a first conductor layer and a second conductor layer and a method of manufacturing the same.

2. Discussion of the Background

In recent years, various display devices have been developed with reduced weight and volume. The display devices with reduced weight and volume include liquid crystal displays, field emission displays, plasma display panels, and organic light emitting display devices. While, past display devices with larger volumes and weight included cathode ray tubes.

Liquid crystal display devices and organic light emitting diode display devices include pixels, and each pixel includes transistors. A transistor includes a gate electrically coupled to a gate line and a first electrode be coupled to a data line. Data voltage may be supplied to the data line. If the transistor is turned on due to the gate line, the first electrode and the second electrode may be electrically coupled. In the case of the liquid crystal display device, the second electrode may be electrically coupled to the pixel electrode, and in the case of the organic light emitting diode display device, the data voltage that is supplied to the second electrode may be supplied to the gate electrode of the driver transistor.

Metal is the main material that forms the gates (i.e., gate electrode, first electrode, and second electrode). Unfortunately, ambient light reflection phenomenon may occur by using metal for gates. The ambient light reflection phenomenon may me more pronounced in curved televisions because while curved televisions may improve image quality, reflected ambient light is focused toward viewers causing viewing discomfort to users when they watch the television.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a display device that may reduce viewing discomfort of users due to reflected ambient light and a method of manufacturing the same.

Exemplary embodiments provide a display device with reduced number of masks additionally required, even if the number of metal layers increases, and a method of manufacturing the same.

Additional aspects will be set forth in the detailed description which follows, and, in part, will be apparent from the disclosure, or may be learned by practice of the inventive concept.

An exemplary embodiment discloses a display device including a gate line, a data line crossing the gate line, and a first transistor including a gate electrode electrically coupled to the gate line and a first electrode electrically coupled to the data line. At least one of the gate electrode of the first transistor, the first electrode of the first transistor, and a second electrode of the first transistor includes at least one of a first conductor layer and a second conductor layer. The first conductor layer includes a first metal layer and a second metal layer disposed on the first metal layer. The second conductor layer includes a third metal layer and a fourth metal layer disposed on the third metal layer. A reflectivity of the second metal layer is lower than a reflectivity of the first metal layer. A reflectivity of the fourth metal layer is lower than a reflectivity of the third metal layer.

An exemplary embodiment also discloses a method of manufacturing a display device including disposing a first conductor layer having a first pattern on a substrate, disposing an insulator layer over the first conductor layer and the substrate, and disposing a second conductor layer having a second pattern and a third pattern on a portion of the insulator layer. The second pattern and the third pattern being electrically disconnected from each other. A level of a current flowing between the second pattern and the third pattern is determined based on a level of a voltage supplied to the first pattern. The disposing of the first conductor layer includes disposing a first metal layer and disposing a second metal layer on the first metal layer. A reflectivity of the second metal layer is lower than a reflectivity of the first metal layer.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic view of a display device according to an exemplary embodiment.

FIG. 2 is a schematic view of a pixel in the display device shown in FIG. 1.

FIG. 3 is another schematic view of a pixel in the display device shown in FIG. 1.

FIG. 4 is a cross-sectional view of a first metal layer in a method of manufacturing a display device according to an exemplary embodiment.

FIG. 5 is a cross-sectional view of forming a second metal layer on a first metal layer in a method of manufacturing a display device according to an exemplary embodiment.

FIG. 6 is a cross-sectional view of forming a first transparent conductive layer on a second metal layer in a method of manufacturing a display device according to an exemplary embodiment.

FIGS. 7, 8, and 9 are cross-sectional views of forming a first transparent conductive layer on a second metal layer in a method of manufacturing a display device according to an exemplary embodiment.

FIG. 10 is a cross-sectional view of forming a third metal layer in a method of manufacturing a display device according to an exemplary embodiment.

FIG. 11 is a cross-sectional view of forming a fourth metal layer on a third metal layer in a method of manufacturing a display device according to an exemplary embodiment.

FIG. 12 is a cross-sectional view of forming a second transparent conductive layer on a fourth metal layer in a method of manufacturing a display device according to an exemplary embodiment.

FIGS. 13, 14, and 15 are cross-sectional views of forming a second transparent conductive layer on a fourth metal layer in a method of manufacturing a display device according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

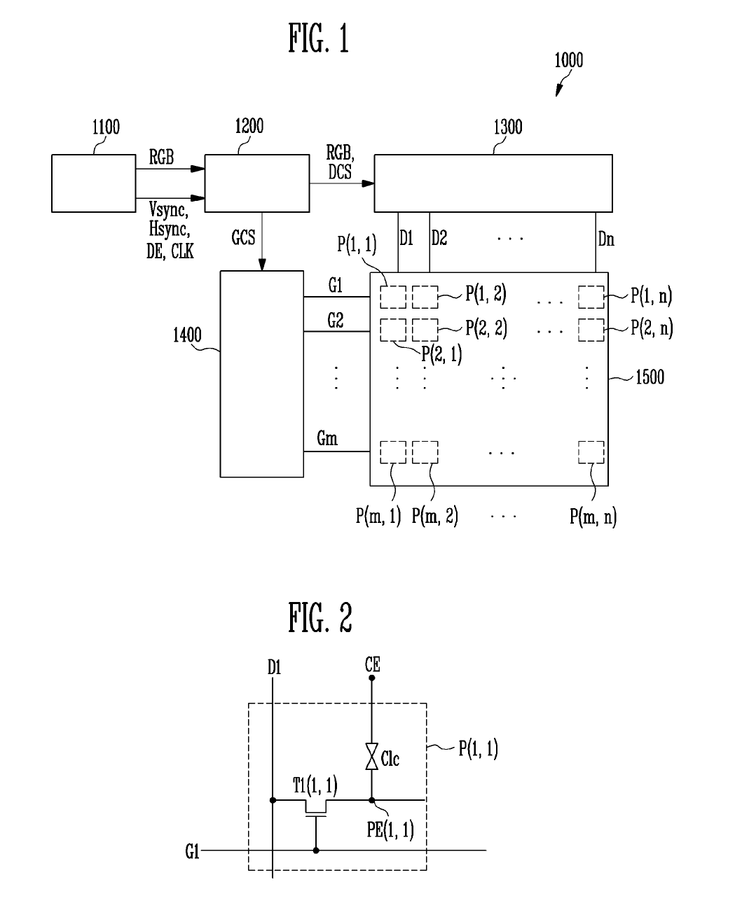

FIG. 1 is a block view for illustrating a display device according to an exemplary embodiment. Referring to FIG. 1, a liquid crystal display device 1000 according to an exemplary embodiment includes a host 1100, a timing controller 1200, a data driver 1300, a gate driver 1400, and a display panel 1500.

The host 1100 may receive an external electrical signal corresponding to a screen displayed from outside and provide it to the timing controller 1200. The host 1100 may include a system on chip with a scaler internally mounted and may convert the received external electrical signal into a data format in a resolution that is proper for displaying image data RGB input from an external video source device onto a display panel 1500. The host 1100 may supply not only image data RGB through an interface (i.e., low voltage differential signaling (LVDS) interface and transition minimized differential signaling (TMDS)) but also vertical synchronization signal (Vsync), horizontal synchronization signal (Hsync), data enable signal (DE), and dot clock (CLK) to the timing controller 1200.

The timing controller 1200 may receive timing signals Vsync, Hsync, DE, and CLK from the host 1100 and generate timing control signals for controlling operation timing of the data driver 1300 and the gate driver 1400. The timing control signals may include a gate timing control signal GCS for controlling operation timing of the gate driver 1400 and a data timing control signal DCS for controlling the operation timing of the data driver 1300 and the polarity of the data voltage. The data timing control signal DCS may control data sampling start timing of the data driver 1300. In addition, image data RGB may be output to the data driver 1300 such that the display panel 1500 may display an image.

The data driver 1300 may latch image data RGB input from the timing controller 1200 in response to the data timing control signal DCS. In addition, the data driver 1300 may sequentially supply data voltages to the data lines D1 to Dn (hereinafter, “D”) in response to the data timing control signal DCS. The data driver 1300 may include multiple source drive integrated circuits (ICs). The source drive ICs may be electrically coupled to the data lines D1 to Dn (where n is a positive integer) of the display panel 1500 by the chip-on-glass (COG) process and the tape automated bonding (TAB) process.

The gate driver 1400 may sequentially supply gate signals to the gate lines G1 to Gm (where m is a positive integer) in response to the gate timing control signal GCS. The gate driver 1400 may be directly formed on a thin film transistor (TFT) array substrate of the display panel 1500 by a gate-in-panel (GIP) method or electrically coupled to the gate lines G1 to Gm (hereinafter G) of the display panel 1500 by a TAB method.

The display panel 1500 may include pixels. The display panel may include pixels P(1, 1), P(1, 2) to P(m, n) (hereinafter, “P”). Each of the pixels P may be divided into the corresponding gate line and data line. For example, a pixel corresponding to a-th gate line Ga (where a is a positive integer that is m or smaller) and b-th data line Db (where b is a positive integer that is n or smaller) may be defined as a pixel P(a, b). The interrelationship between the pixel P(a, b), the gate line Ga and the data line Db is described in detail with reference to FIG. 2.

FIG. 2 is a view for illustrating an exemplary embodiment of a pixel in the display device of FIG. 1. For brevity, the pixel P(1, 1) corresponding to the first gate line G1 and the first data line D1 is described as an example. The pixel P(1, 1) corresponds to the pixel in the liquid crystal display device.

The pixel P(1, 1) corresponding to the first gate line G1 and the first data line D1 may include a first transistor T1(1, 1), a pixel electrode PE(1, 1), and a liquid crystal Clc.

A gate electrode of the first transistor T1(1, 1) may be electrically coupled to the gate line G1. A first electrode of the first transistor T1(1, 1) may be electrically coupled to the data line D1. A second electrode of the first transistor T1(1, 1) may be electrically coupled to the pixel electrode PE(1, 1). The first electrode may be a source electrode or a drain electrode. The second electrode may be a source electrode or a drain electrode and may be a completely different electrode from the first electrode. For example, if the first electrode is a source electrode, the second electrode may be a drain electrode, and if the first electrode is a drain electrode, the first electrode may be a source electrode. In order to maintain the voltage level of the pixel electrode PE(1, 1) for a certain period, the pixel electrode PE(1, 1) may be electrically coupled to an end of an additional capacitor (not shown).

If the gate signal is supplied to the gate line G1, the first transistor T1(1, 1) may be turned on. As the first transistor T1(1, 1) is turned on, the data voltage supplied to the data line D1 may be supplied to the pixel electrode PE(1, 1). The arrangement of the liquid crystal Clc may change based on the level of the pixel electrode PE(1, 1) and a common electrode CE. Because of the change in the arrangement of the liquid crystal Clc, the strength of the light displayed to user changes.

FIG. 3 is a view for illustrating an exemplary embodiment of the pixel in the display device. The pixel P′(1, 1) may correspond to the pixel in the organic light emitting diode display device.

The pixel P′(1, 1) corresponding to the first gate line G1 and the first data line D1 may include a first transistor T1′(1, 1), a driver transistor DT(1, 1), an organic light emitting diode OLED(1, 1) and a storage capacitor Cs.

A gate electrode of the first transistor T1′(1, 1) may be electrically coupled to the gate line G1, a first electrode of the first transistor T1′(1, 1) may be electrically coupled to the data line D1, and a second electrode of the first transistor T1′(1, 1) may be electrically coupled to a first node N1. A gate electrode of the driver transistor DT(1, 1) may be electrically coupled to the first node N1, a first electrode of the driver transistor DT(1, 1) may be electrically coupled to a first power supply line VDDL, and a second electrode of the driver transistor DT(1, 1) may be electrically coupled to an anode electrode of the organic light emitting diode OLED(1, 1). Similar to the first transistor T1(1, 1) shown in FIG. 2, the first electrode of the first transistor T1′(1, 1) may be a source electrode or a drain electrode, and the second electrode may be a source electrode or a drain electrode but may be a completely different electrode from the first electrode. In an exemplary embodiment shown in FIG. 3, the second electrode of the first transistor T1′(1,1) is electrically coupled to the first node N1 and the gate electrode of the driver transistor DT(1, 1) is electrically coupled to the first node Ni. If the voltage supplied to the second electrode of the first transistor T1′(1, 1) meets certain conditions, it may be supplied to the gate electrode of the driver transistor DT(1, 1).

One end of the storage capacitor Cs may be electrically coupled to the first node N1, and the other end of the storage capacitor Cs may be electrically coupled to the first power supply line VDDL. The level of the voltage stored in the storage capacitor Cs may correspond to a difference between the first electrode of the driver transistor DT(1, 1) and the voltage level of the gate electrode of the driver transistor DT(1, 1).

The anode electrode of the organic light emitting diode OLED(1, 1) may be electrically coupled to the second electrode of the driver transistor DT(1, 1), and a cathode electrode of the organic light emitting diode OLED(1, 1) may be electrically coupled to a second power supply line VSSL.

If the gate signal is supplied to the gate line G1, the first transistor T1′(1, 1) may be turned on. Because the first transistor T1′(1, 1) is turned on, the data voltage supplied to the data line D1 may be supplied to the gate electrode of the driver transistor DT(1, 1). As a result, the level of the voltage stored in the storage capacitor Cs may change, and the level of current flowing between the first electrode and the second electrode of the driver transistor DT(1, 1) may change. Since the level of the current supplied to the organic light emitting diode OLED(1, 1) changes, the strength of the light emitted from the organic light emitting diode OLED(1, 1) and the strength of the light displayed to the users may change.

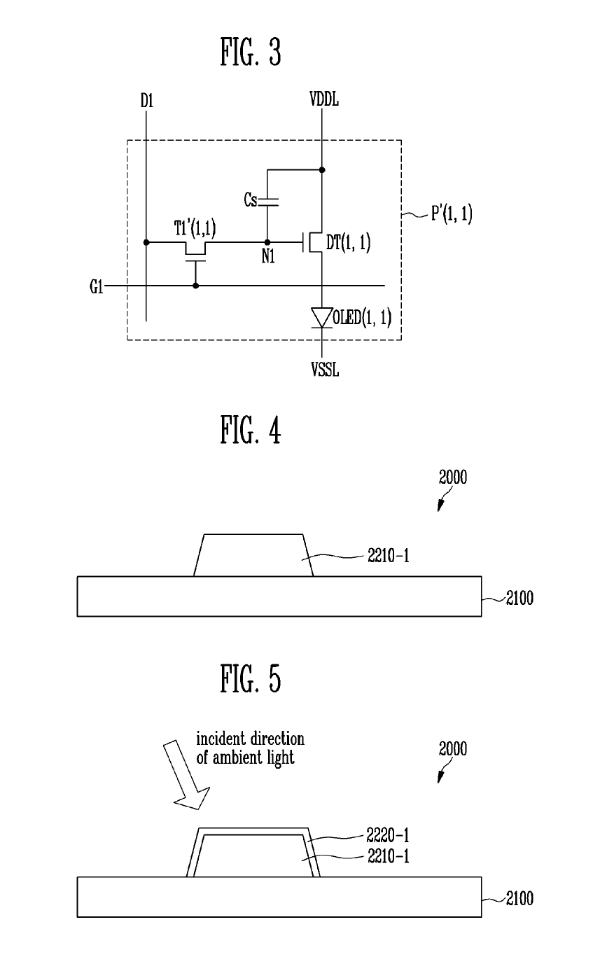

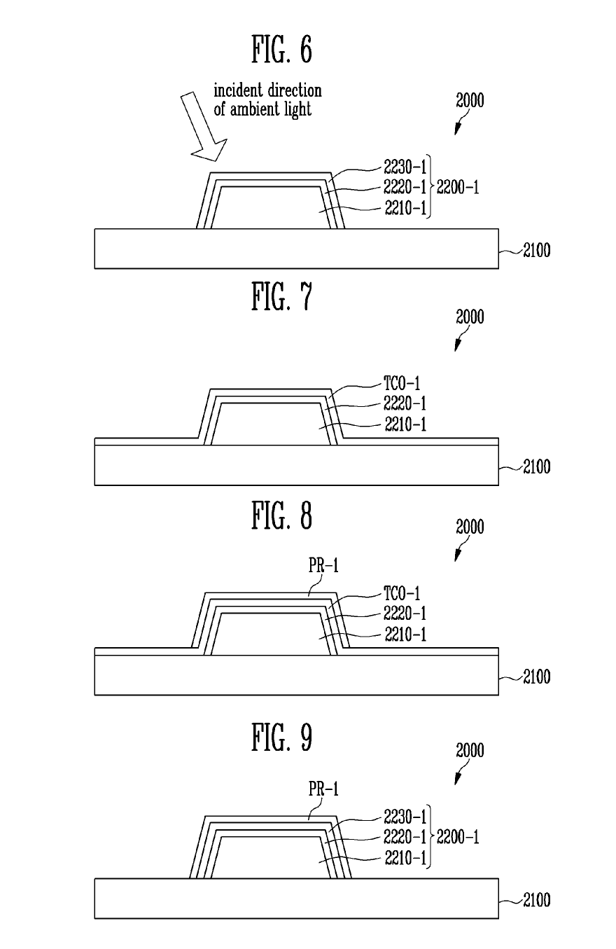

FIG. 4 is a view for illustrating a step of forming a first metal layer in a method of manufacturing a display device according to an exemplary embodiment. FIG. 5 is a view for illustrating a step of forming a second metal layer on a first metal layer in a method of manufacturing a display device according to an exemplary embodiment. FIG. 6 is a view for illustrating a step of forming a first transparent conductive layer on a second metal layer in a method of manufacturing a display device according to an exemplary embodiment.

A material forming a substrate 2100 may be transparent (i.e., plastic and/or glass). A first metal layer 2210-1 may be formed on the substrate 2100. The first metal layer 2210-1 is a portion corresponding to a first pattern among the entire first metal layer. The first metal layer 2210-1 may be formed by various methods. For example, after a metal layer is formed on an entire surface above the substrate 2100, a sensitive layer may be patterned using a mask, thereby exposing a portion of the metal layer, and after the portion of the exposed metal layer is etched, the remaining sensitive layer may be removed. Alternatively, after the sensitive layer is patterned using a mask to expose a portion of the substrate 2100, a metal layer is formed on an exposed portion of the sensitive layer and substrate, and a sensitive layer and a metal layer formed on the sensitive layer is removed to form the first metal layer 2210-1. A material forming the first metal layer 2210-1 may include at least one of copper (Cu) and titanium (Ti).

After the first metal layer 2210-1 is formed, a second metal layer 2220-1 may be formed on the first metal layer 2210-1. The second metal layer 2220-1 is a portion corresponding to a first pattern among the entire second metal layer. The step in which a second metal layer 2220-1 is formed on the first metal layer 2210-1 may include a plating step based on the first metal layer. In particular, the second metal layer 2220-1 may be formed through plating without using a sensitive layer and a mask. The first metal layer 2210-1 and the substrate 2100 may be coupled to any one of a positive electrode and a negative electrode of a direct current power. After the metal source is coupled to the remaining electrode of the direct current power, electroplating may be performed in the case the substrate 2100 and the metal source are withdrawn into an electroplating solution. Alternatively, electroless plating may be performed just by the substrate 2100 being withdrawn into electroless plating solution containing a metal material. If the material for the substrate 2100 is glass, since the substrate 2100 is formed of a material through which current does not flow and which does not react with the electroless plating solution, plating may not occur on the substrate 2100. On the other hand, since the first metal layer 2210-1 is formed of a conductive material (i.e., material that current flows through) that reacts with the electroless plating solution, plating occurs on the first metal layer 2210-1.

Therefore, a second metal layer 2220-1 may be formed only on the first metal layer 2210-1. The material forming the second metal layer 2220-1 may include at least one of tin (Sn), nickel (Ni), and chrome (Cr). The second metal layer 2220-1 may be a black metal layer. The black metal layer refers to a metal layer having low reflectivity. For example, a liquid crystal display device may include a black matrix that may appear black to the naked eye if reflectivity is 3% or less. If the reflectivity of the second metal layer 2220-1 is 3% or less, the second metal layer 2220-1 is a black metal layer. Therefore, the reflectivity of the second metal layer 2220-1 may be lower than the reflectivity of the first metal layer 2210-1.

After the second metal layer 2220-1 is formed, a first transparent conductive layer 2230-1 may be formed on the second metal layer 2220-1. The first transparent conductive layer 2230-1 refers to a portion that corresponds to the first pattern among the entire first transparent conductive layer. In an exemplary embodiment that refers to FIG. 6, the step in which a first transparent conductive layer 2230-1 is formed on a second metal layer 2220-1 may include the plating step based on the second metal layer 2220-1. More specifically and similar to FIG. 5, the first transparent conductive layer 2230-1 may be formed by electroplating or electroless plating. If a material of a substrate 2100 is glass (a non-conductive material), the substrate 2100 does not react with electroless plating solution, meaning plating does not occur on the substrate 2100. On the other hand, since the second metal layer 2220-1 is formed of a conductive material and the second metal layer 2220-1 reacts with electroless plating solution, meaning plating occurs on the second metal layer 2220-1. Accordingly, the first transparent conductive layer 2230-1 may be formed only on the second metal layer 2220-1. A material that forms the first transparent conductive layer 2230-1 may include at least one of indium tin oxide (ITO), indium zinc oxide (IZO), zinc indium oxide (ZIO), and zinc tin oxide (ZTO). The first conductor layer 2200-1 may include a first metal layer 2210-1, a second metal layer 2220-1, and a first transparent conductive layer 2230-1. The first conductor layer 2200-1 refers to a portion that corresponds to a first pattern among the entire first conductor layer, and the first conductor layer 2200-1 may correspond to a gate electrode of a first transistor T1(1, 1), T1′(1, 1).

If the second metal layer 2220-1 is a black metal layer, the first conductor layer 2200-1 including the second metal layer 2220-1 may reflect a significantly lower amount of ambient light compared the amount of light of ambient light a first conductor layer 2200-1 that does not include a second metal layer 2220-1 as a black metal layer (i.e., a first conductor layer 2200-1 that only includes the first metal layer 2210-1) Therefore, a degree of discomfort that users experience from the ambient light may significantly decrease by including the second metal layer 2220-1. In addition, if the first transparent conductive layer 2230-1 is formed on the second metal layer 2220-1, a portion of a light that is reflected by the second metal layer 2220-1 is scattered by the first transparent conductive layer 2230-1, and the amount of reflected light that reaches users may further decrease. More specifically, the degree of discomfort that users experience from the ambient light may be significantly reduced by the first transparent conductive layer 2230-1. Even if a portion of the ambient light that travels through the first transparent conductive layer 2230-1 is reflected by the second metal layer 2220-1, the reflected light and the ambient light that travels through the first transparent conductive layer 2230-1 may be subject to destructive interference. To this end, a thickness of the first transparent conductive layer 2230-1 may be adjusted. As described with reference to FIG. 6, if the first transparent conductive layer 2230-1 is formed by plating, the first transparent conductive layer 2230-1 may be formed without additional photo processing. Therefore, even if the transparent conductive layer is formed, manufacture costs may only be slightly higher for this additional step.

FIGS. 7, 8, and 9 are views for illustrating a step of forming a first transparent conductive layer on a second metal layer in a method of manufacturing a display device according to an exemplary embodiment. A step of forming the first transparent conductive layer on the second metal layer may include forming a transparent conductive layer on the second metal layer, patterning a sensitive layer such that a portion of sensitive layer that corresponds to a first pattern among the transparent conductive layer is not exposed to outside the first metal layer region. In other words, the transparent conductive layer covers the second metal layer and the substrate but the sensitive layer only covers the portion of the transparent conductive layer that covers the second metal layer), etching a portion of the transparent conductive layer that is exposed over the second metal layer (i.e., the portion of the transparent conductive layer that only covers the substrate) and removing the sensitive layer.

FIG. 7 is a view for illustrating a step of forming a transparent conductive layer on a second metal layer. A transparent conductive layer TCO-1 may be formed on a second metal layer 2220-1 and the substrate 2100. The portion of the transparent conductive layer TCO-1 that only covers the substrate 2100 is considered to be outside the first pattern or the first metal region.

FIG. 8 is a view for illustrating a step of patterning a sensitive layer such that a portion of the sensitive layer corresponding to a first pattern among a transparent conductive layer is not exposed outside the first metal layer region. A sensitive layer PR-1 may be formed on the transparent conductive layer TCO-1 over the second metal layer 2220-1, but not over the transparent conductive layer TCO-1 that only covers the substrate 2100. The sensitive layer PR-1 may be patterned such that a portion of the sensitive layer PR-1 corresponding to a first pattern is not exposed to outside the first metal layer region.

FIG. 9 is a view for illustrating a step of etching the exposed portion of the transparent conductive layer over the substrate. Due to etching, the portion of the transparent conductive layer TCO-1 that is exposed to the outside the first metal region is removed. On the other hand, the portion that is not exposed to the outside of the first metal region due to the sensitive layer PR-1 is not removed. The portion of the transparent conductive layer TCO-1 that remains after etching is the first transparent conductive layer 2230-1. Thereafter, the step of removing the sensitive layer may be performed. As the sensitive layer PR-1 is removed, the step of forming the first transparent conductive layer 2230-1 on the second metal layer may be completed. While the manufacturing method illustrated and described with reference to FIG. 9 may be different from the manufacturing method illustrated and described with reference to FIGS. 6, once the first transparent conductive layer is formed and the sensitive layer PR-1 is removed in FIG. 9, the first conductor layer 2200-1 has the same shape in FIGS. 6 and 9. As illustrated with reference to FIGS. 7 to 9, if the first transparent conductive layer 2230-1 is formed from the forming of the transparent conductive layer, the patterning of the sensitive layer, the etching of the transparent conductive layer and the removal of the sensitive layer, the first transparent conductive layer 2230-1 may be formed using a regular process that has already been established. Accordingly, it may only take a short while to optimize process conditions for manufacturing.

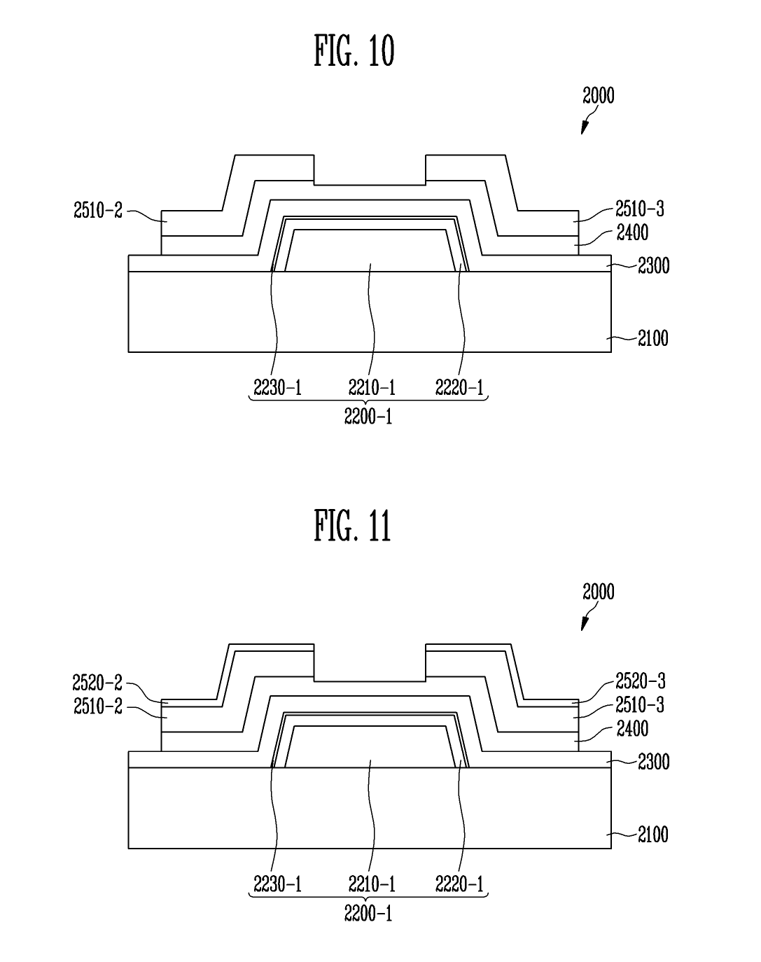

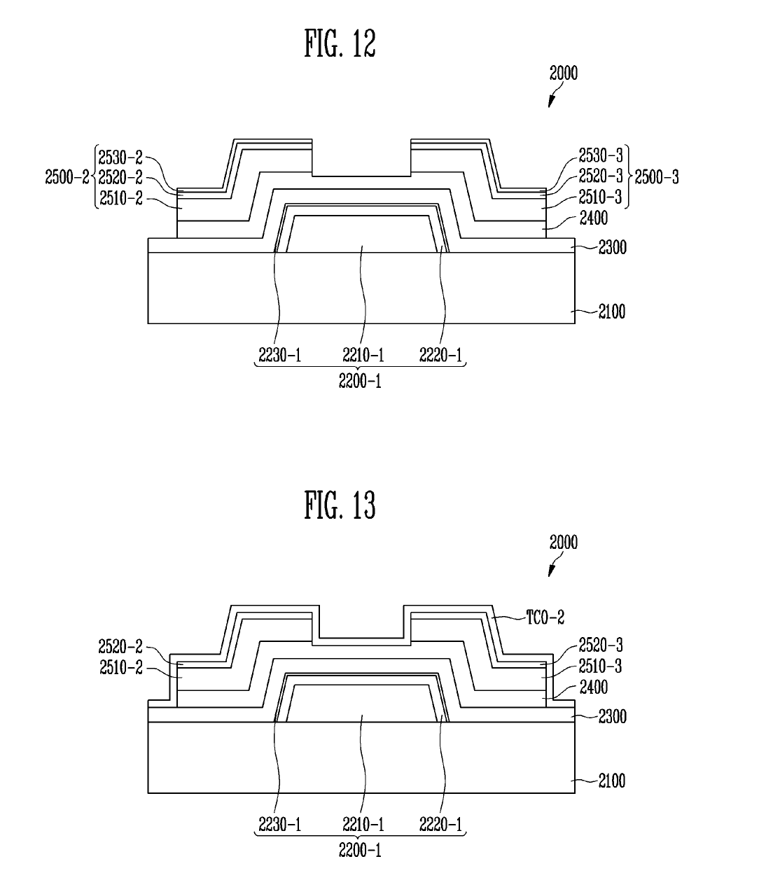

FIG. 10 is a view for illustrating a step of forming a third metal layer in a method of manufacturing a display device according to an exemplary embodiment. FIG. 11 is a view for illustrating a step of forming a fourth metal layer on a third metal layer in a method of manufacturing a display device according to an exemplary embodiment. FIG. 12 is a view for illustrating a step of forming a second transparent conductive layer on a fourth metal layer in a method of manufacturing a display device according to an exemplary embodiment.

Referring to FIG. 10, an insulator layer 2300 may be formed on a first conductor layer 2200-1. More specifically, after FIG. 6, the step of forming the insulator layer 2300 may be performed to not expose at least a portion of the first pattern to outside the first metal region. In other words, a portion of the insulator layer 2300 may be formed directly over the first transparent conductive layer 2230-1 and a different portion of the insulator layer 2300 may be formed directly over the substrate 2100. A SiNₓ layer 2400 may be also formed on the insulator layer 2300 such that the SiNₓ layer 2400 covers the portion of the insulator layer 2300 that is formed directly over the first transparent conductive layer 2230-1 and some of the portion of the insulator layer 2300 that is formed directly over the substrate 2100. The SiNₓ layer 2400 may be transparent.

After the SiNx layer 2400 is formed, a third metal layer 2510-2 and 2510-3 may be formed on the SiNₓ layer 2400. The third metal layer 2510-2 refers to a portion that corresponds to a second pattern among the entire third metal layer. The third metal layer 2510-3 refers to a portion that corresponds to a third pattern among the entire third metal layer. The third metal layer 2510-2 and 2510-3 is formed is similar manner as the first metal layer 2210-1, thus these similar method steps are omitted for brevity. A material that forms the third metal layer 2510-2 and 2510-3 may include at least one of copper (Cu) and titanium (Ti).

After the third metal layer 2510-2 and 2510-3 is formed, a fourth metal layer 2520-2 and 2520-3 may be formed on the third metal layer 2510-2 and 2510-3. The step of forming the fourth metal layer 2520-2 and 2520-3 on the third metal layer 2510-2 and 2510-3 may include a plating step based on the first metal layer. The fourth metal layers 2520-2 and 2520-3 are formed in a similar manner as the second metal layer 2220-1. Thus, these similar method steps are omitted for brevity. The fourth metal layer 2520-2 refers to a portion that corresponds to a second pattern among the entire fourth metal layer. The fourth metal layer 2520-3 refers to a portion that corresponds to a third pattern among the entire fourth metal layer. Similar to the second metal layer 2220-1, a material that forms the fourth metal layer 2520-2 and 2520-3 may include at least one of tin (Sn), nickel (Ni), and chrome (Cr). The fourth metal layer 2520-2 and 2520-3 may be a black metal layer. Accordingly, reflectivity of the fourth metal layer 2520-2 and 2520-3 may be lower than the reflectivity of the third metal layer 2510-2 and 2510-3. If the material and the manufacturing process of the second metal layer 2220-1 and the material and the manufacturing process of the fourth metal layers 2520-2 and 2520-3 are the same, the reflectivity of the fourth metal layers 2520-2 and 2520-3 may correspond to the reflectivity of the second metal layer 2220-1.

After the fourth metal layer 2520-2 and 2520-3 is formed, a second transparent conductive layer 2530-2 and 2530-3 may be formed on the fourth metal layer 2520-2 and 2520-3. The second transparent conductive layer 2530-2 refers to a portion that corresponds to a second pattern among the entire second transparent conductive layer, and the second transparent conductive layer 2530-3 refers to a portion that corresponds to a third pattern among the entire second transparent conductive layer. In an exemplary embodiment with reference to FIG. 12, the step of forming the second transparent conductive layer 2530-2 and 2530-3 on the fourth metal layer 2520-2 and 2520-3 may include the plating step based on the fourth metal layer 2520-2 and 2520-3. Since the plating step based on the fourth metal layer 2520-2 and 2520-3 is similar to the plating step based on the second metal layer 2220-1, the repeated details will be omitted for brevity. Similar to the first transparent conductive layer 2230-1, the material that forms the second transparent conductive layer 2530-2 and 2530-3 may include at least one of indium tin oxide (ITO), indium zinc oxide (IZO), zinc indium oxide (ZIO), and zinc tin oxide (ZTO). The second conductor layer 2500-2 may include a third metal layer 2510-2, a fourth metal layer 2520-2, and a second transparent conductive layer 2530-2 and refers to a portion that corresponds to the second pattern among the entire second conductor layer. The second conductor layer 2500-3 may include a third metal layer 2510-3, a fourth metal layer 2520-3, and a second transparent conductive layer 2530-3 and refers to a portion that corresponds to the third pattern among the entire second conductor layer. As shown in FIG. 12, the second pattern and the third pattern are disconnected from each other electrically, the second conductor layer 2500-2 may correspond to a first electrode of a first transistor T1(1, 1) and T1′(1, 1), and the second conductor layer 2500-3 may correspond to a second electrode of the first transistor T1(1, 1) and T1′(1, 1). Accordingly, the level of the current flowing between the second conductor layer 2500-2 and the second conductor layer 2500-3 may be determined based on the level of the voltage supplied to the first conductor layer 2200-1. Since the second conductor layer 2500-2 and 2500-3 may include not only the third metal layers 2510-2 and 2510-3 but also the fourth metal layers 2520-2 and 2520-3 and the second transparent conductive layer 2530-2 and 2530-3, it is already described that the amount of the reflected light that reaches user decreases. A SiNₓ layer (not shown) may be additionally formed on the second transparent conductive layers 2530-2 and 2530-3. Even if the additional SiNₓ layer (not shown) is transparent, due to the fourth metal layer 2520-2 and 2520-3 and the second transparent conductive layer 2530-2 and 2530-3, the degree of the light being reflected by the second conductor layer 2500-2 and 2500-3 among the ambient light may significantly decrease.

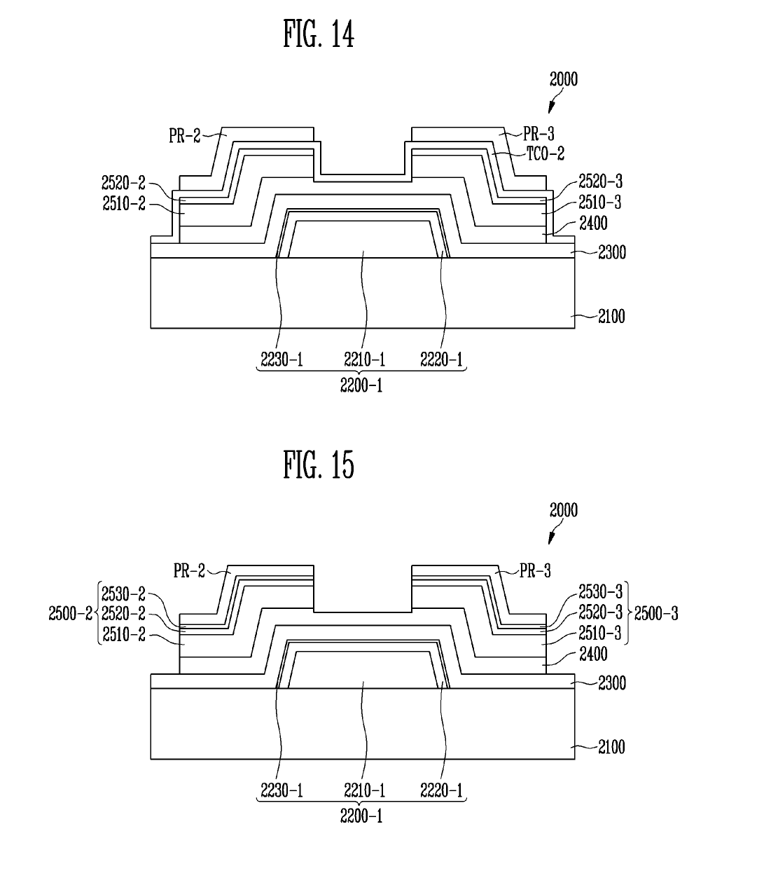

FIGS. 13, 14, and 15 are views for illustrating a step of forming a second transparent conductive layer on a fourth metal layer in a method of manufacturing a display device according to an exemplary embodiment. The step of forming a second transparent conductive layer on the fourth metal layer may include a step of forming a transparent conductive layer on the fourth metal layer, a step of patterning a sensitive layer such that a portion of the sensitive layer corresponding to second and third patterns among the transparent conductive layer is not exposed to the outside (i.e., the sensitive layer only covers portions for the transparent conductive layer that is directly over the fourth metal layer 2520-2 and 2520-3 and not portions of the transparent conductive layer that directly covers the insulator layer 2300), a step of etching the exposed portion among the transparent conductive layer over the fourth metal layer and a step of removing the sensitive layer.

FIG. 13 is a view for illustrating the step of forming the transparent conductive layer on the fourth metal layer. A transparent conductive layer TCO-2 may be formed on the fourth metal layer 2520-2 and 2520-3.

FIG. 14 is a view for illustrating a step of patterning a sensitive layer such that a portion corresponding to second and third patterns among the transparent conductive layer is not exposed to the outside (i.e., the sensitive layer does not cover portions of the transparent conductive layer that directly covers the insulator layer 2300). Sensitive layers PR-2 and PR-3 may be formed on the portion of the transparent conductive layer TCO-2 that is directly over the fourth metal layer 2520-2 and 2520-3. The sensitive layer PR-2 may be patterned such that the portion corresponding to the second pattern among the transparent conductive layer TCO-2 is not exposed to the outside (i.e., the sensitive layer does not cover portions of the transparent conductive layer that directly covers the insulator layer 2300). The sensitive layer PR-3 may be patterned such that the portion corresponding to the third pattern among the transparent conductive layer TCO-2 is not exposed to the outside (i.e., the sensitive layer does not cover portions of the transparent conductive layer that directly covers the insulator layer 2300). Referring to FIG. 14, the portion of the transparent conductive layer TCO-2 that does not correspond to the second pattern or the third pattern among the transparent conductive layer TCO-2 is exposed to the outside (i.e., the portion of the transparent conductive layer TCO-2 that directly covers the insulator layer 2300).

FIG. 15 is a view for illustrating a step of etching the portion exposed among the transparent conductive layer over the fourth metal layer. The portion of the transparent conductive layer TCO-2 that directly covers the insulator layer 2300 may be removed by etching.

On the other hand, the portion of the transparent conductive layer TCO-2 that is not directly covering the insulator layer 2300. The transparent conductive layer TCO-2 that is patterned by the etching (i.e., the transparent conductive layer TCO-2 that remains) is the second transparent conductive layer 2530-2 and 2530-3. The second transparent conductive layer 2530-2 refers to a portion of the transparent conductive layer TCO-2 that corresponds to the second pattern among the entire transparent conductive layer TCO-2, and the second transparent conductive layer 2530-3 refers to a portion the transparent conductive layer TCO-2 that corresponds to the third pattern among the entire transparent conductive layer TCO-2. Thereafter, the step of removing the sensitive layers PR-2 and PR-3 may be performed. The step of forming the second transparent conductive layer 2530-2 and 2530-3 over the fourth metal layer 2520-2 and 2520-3 due to removal of the sensitive layers PR-2 and PR-3 may be completed. Although the manufacturing method described with reference to FIG. 15 may be different from the manufacturing method described with reference to FIG. 12, after the step of forming the second transparent conductive layers 2530-2 and 2530-3 is completed in FIG. 15 (i.e., the sensitive layers PR-2 and PR-2 are removed), final shape may have a shape similar to what is shown in

FIG. 12. Since advantages and disadvantages of forming transparent conductive layer using plating versus using sensitive layer have already been described, the repetitive description will be omitted for brevity.

Exemplary embodiments describe a display device and a method of manufacturing a display device that may reduce discomfort experienced by users due to reflected ambient light. Exemplary embodiments also describe a display device and a method manufacturing a display device with a reduced number of masks even with an increase in the number of metals layers in the display device.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display device, comprising:
a gate line;
a data line crossing the gate line; and
a first transistor comprising a gate electrode electrically coupled to the gate line and a first electrode electrically coupled to the data line,
wherein at least one of the gate electrode of the first transistor, the first electrode of the first transistor, and a second electrode of the first transistor comprises at least one of a first conductor layer and a second conductor layer,
wherein the first conductor layer comprises a first metal layer and a second metal layer disposed on the first metal layer, and the second conductor layer comprises a third metal layer and a fourth metal layer disposed on the third metal layer,
wherein a reflectivity of the second metal layer is lower than a reflectivity of the first metal layer, and a reflectivity of the fourth metal layer is lower than a reflectivity of the third metal layer.

2. The display device of claim 1, wherein the second metal layer comprises at least one of tin (Sn), nickel (Ni), and chrome (Cr).

3. The display device of claim 2, wherein the fourth metal layer comprises at least one of tin (Sn), nickel (Ni), and chrome (Cr).

4. The display device of claim 1, wherein the first conductor layer further comprises a first transparent conductive layer disposed on the second metal layer, and
the second conductor layer further comprises a second transparent conductive layer disposed on the fourth metal layer.

5. The display device of claim 4, wherein the first transparent conductive layer comprises at least one of indium tin oxide (ITO), indium zinc oxide (IZO), zinc indium oxide (ZIO), and zinc tin oxide (ZTO).

6. The display device of claim 5, wherein the second transparent conductive layer comprises at least one of indium tin oxide (ITO), indium zinc oxide (IZO), zinc indium oxide (ZIO), and zinc tin oxide (ZTO).

7. The display device of claim 1, further comprising:
a common electrode, a pixel electrode, and a liquid crystal layer changing in arrangement based on a voltage level of the common electrode and the pixel electrode,
wherein the second electrode of the first transistor is electrically coupled to the pixel electrode.

8. The display device of claim 1, further comprising:
a driver transistor;
a storage capacitor;
an organic light emitting diode;
a first power supply line; and
a second power supply line,
wherein the second electrode of the first transistor is electrically coupled to a first node,
wherein the gate electrode of the driver transistor and a first end of the storage capacitor are electrically coupled to the first node,
wherein the first electrode of the driver transistor and a second end of the storage capacitor are electrically coupled to the first power supply line,
wherein a second electrode of the driver transistor is electrically coupled to an anode electrode of the organic light emitting diode,
wherein a cathode electrode of the organic light emitting diode is electrically coupled to is the second power supply line.

9. A method of manufacturing a display device, comprising:
disposing a first conductor layer having a first pattern on a substrate;
disposing an insulator layer over the first conductor layer and the substrate; and
disposing a second conductor layer having a second pattern and a third pattern on a portion of the insulator layer, the second pattern and the third pattern being electrically disconnected from each other,
wherein a level of a current flowing between the second pattern and the third pattern is determined based on a level of a voltage supplied to the first pattern,
wherein the disposing of the first conductor layer, comprises:
disposing a first metal layer; and
disposing a second metal layer on the first metal layer,
wherein a reflectivity of the second metal layer is lower than reflectivity of the first metal layer.

10. The method of claim 9, wherein the disposing of the second metal layer comprises plating based on the first metal layer and the second metal layer is disposed only at a place where the first metal layer is disposed.

11. The method of claim 9, wherein the disposing of the first conductive layer further comprises disposing a first transparent conductive layer on the second metal layer.

12. The method of claim 11, wherein the disposing of the first transparent conductive layer on the second metal layer comprises plating based on the second metal layer, and
the first transparent conductive layer is disposed only at a place where the second metal layer is disposed.

13. The method of claim 11, wherein the disposing of the first transparent conductive layer on the second metal layer, further comprises:
patterning a first sensitive layer to only cover a first portion of the first transparent conductive layer that covers the second metal layer;
etching a second portion of the first transparent conductive layer that does not cover the second metal layer; and
removing the first sensitive layer.

14. The method of claim 9, wherein the disposing of the second conductor layer, further comprises:
disposing a third metal layer; and
disposing a fourth metal layer on the third metal layer,
wherein a reflectivity of the fourth metal layer is lower than a reflectivity of the third metal layer.

15. The method of claim 14, wherein the disposing of the fourth metal layer comprises plating based on the third metal layer and the fourth metal layer is disposed only at a place where the third metal layer is disposed.

16. The method of claim 14, wherein the second metal layer and the fourth metal layer comprise at least one of tin (Sn), nickel (Ni), and chrome (Cr).

17. The method of claim 14, wherein the disposing of the second conductive layer further comprises disposing a second transparent conductive layer on the fourth metal layer.

18. The method of claim 17, wherein the disposing of the second transparent conductive layer on the fourth metal layer comprises plating based on the fourth metal layer and the second transparent conductive layer is formed only at a place where the fourth metal layer is formed.

19. The method of claim 17, wherein the disposing of the second transparent conductive layer on the fourth metal layer further comprises:
patterning a second sensitive layer to only cover a first portion of the second transparent conductive layer that covers the third and fourth metal layers;
etching a second portion of the second transparent conductive layer that does not cover the third and fourth metal layers; and
removing the second sensitive layer.

20. The method of claim 17, wherein the first transparent conductive layer and the second transparent conductive layer comprises at least one of indium tin oxide (ITO), indium zinc oxide (IZO), zinc indium oxide (ZIO), and zinc tin oxide (ZTO).
